(19) United States
(12) Patent Application Publication
(10) Pub. No.: US 2008/0241413 A1
(43) Pub. Date: Oct. 2, 2008

(54) Plasma tool for forming porous diamond films for semiconductor applications

(76) Inventors: Kramadhati V. Ravi, Atherton, CA (US); Jerry W. Zimmer, Saratoga, CA (US)

Correspondence Address: TROP PRUNER & HU, PC, 1616 S. VOSS ROAD, SUITE 750, HOUSTON, TX, 77057-2631, US

(21) Appl. No.: 11/728,458

(22) Filed: Mar. 26, 2007

(51) Int. Cl. H05H 1/24; C23C 16/44

(52) U.S. Cl. 427/450; 118/723 R

(57) ABSTRACT

A plasma tool may be provided to facilitate the deposition of diamond films on substrates. The plasma tool provides a heater in the form of a screen whose position with respect to a substrate may be adjusted. A mixture of hydrocarbon and hydrogen gases may be ejected from a spray shower head type spray nozzle through the screen and onto the substrate. Because of the high speed of the ejected gas mixture, very high flow rates and relatively high reaction rates may be achieved in some embodiments without using excessive temperatures. A chuck may hold the substrate for deposition. The chuck may include a liquid coolant system to cool the substrate to avoid excessive temperatures that might otherwise damage other components on the substrate.

### BACKGROUND

This invention relates generally to the fabrication of integrated circuits.

As the dimensions of integrated circuits have become smaller and the speed of logic and microprocessor products have increased, a limit is faced after which proceeding in the same fashion will no longer produce the corresponding speed and performance improvements. The RC time constant associated with the interconnects in integrated circuits and the related dielectrics will ultimately slow down the speed improvements achieved by reducing device dimensions.

Thus, interlayer dielectric materials are being developed with decreasing dielectric constants below that of traditional silicon dioxide dielectric. Currently, many such dielectrics are materials that have low mechanical strength as a result of using doped oxides. An example is carbon doped oxide. Dielectric constant materials made from organic materials, such as spin-on dielectric, may also exhibit lower mechanical strength.

The lower mechanical strength of these decreased dielectric constant materials leads to mechanical and structural problems during wafer processing, assembly, and packaging operations. Consequently, there is a need for low dielectric constant materials with good mechanical strength that can withstand wafer processing and assembly operations and so that the resulting products are reliable in operation.

Pure diamond films may be synthesized by various chemical vapor deposition techniques to have very high strength and a low dielectric constant. Diamond films with lower dielectric constants and higher moduluses would be desirable. One approach for reducing the dielectric constants of these films, while still maintaining adequate mechanical properties, is to introduce porosity into the films.

Thus, there is a need for ways to introduce porosity into diamond films used for semiconductor applications.

### BRIEF DESCRIPTION OF THE DRAWINGS

FIG. 1 is an enlarged, schematic depiction of one embodiment of the present invention at an early stage; and

FIG. 2 is a schematic depiction of a chamber for use in one embodiment of the present invention.

### DETAILED DESCRIPTION

Diamond and diamond-like carbon films are generally synthesized using plasma activated chemical vapor deposition processes using mixtures of hydrocarbon, such as methane, and hydrogen. Depending on the deposition conditions, these films may reveal a range of mechanical, electronic, and electrochemical properties that depend on the ratio of sp³ (diamond-like) to sp² (graphite-like) bonds. For synthesizing higher purity diamond films without non-diamond forms of carbon (e.g., graphite, amorphous carbon, etc.), a low methane concentration and a supersaturation of hydrogen may be used. As the methane concentration is increased, the percentage of non-diamond forms of carbon increases.

When such mixed phase materials are subjected to an etching process in an atomic hydrogen environment, the non-diamond forms of carbon are preferentially etched. At the same time, the hydrogen does not substantially attack the diamond form of carbon. The etching of the non-diamond form of carbon results in the generation of porosity in the film with the attendant reduction in the dielectric constant of the film. Since much of the remaining carbon is in the form of diamond bonded material (sp³ hybridization), the mechanical strength of these films can be high in some cases.

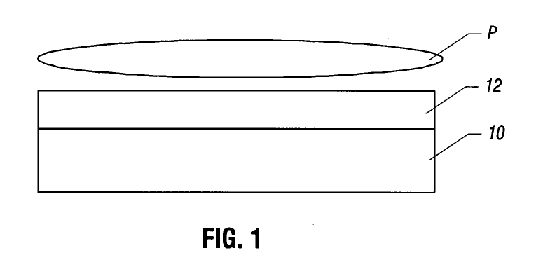

Referring to FIG. 1A, a substrate 10 supports a carbon containing film 12. The film 12 may be a mixed phase carbon film including sp² and sp³ hybridizations formed by plasma enhanced chemical vapor deposition (PECVD).

The sp² carbon concentration in the film 12 may be increased by increasing the methane concentration in the plasma tool used to form the film 12. In one embodiment, from 5 to 30 atomic percent methane may be used to initially deposit the film 12. While conventionally diamond film is made in a steady state process that ends up with pure diamond, here, the goal is to form a mixed phase film. The remainder of the atmosphere in the plasma tool may be primarily hydrogen gas.

The final film 12 may be built in a series of layers. Each layer may be between 500 and 1000 Angstroms thick in one embodiment. Each layer of film 12 may be formed by injecting hydrogen and a hydrocarbon into a plasma tool. A plasma is stricken to obtain an atomic hydrogen plasma by converting the hydrogen gas to atomic hydrogen.

The film 12 may be exposed to atomic hydrogen plasma, indicated as P in FIG. 1A, to selectively etch the non-diamond carbon hybridization.

A new film layer (not shown) may be deposited on top of the previous film 12. The process may then be repeated until the desired total film thickness is achieved. For example, three or more layers may be built up to form the final film thickness. In one embodiment, ten layers may be built up successively.

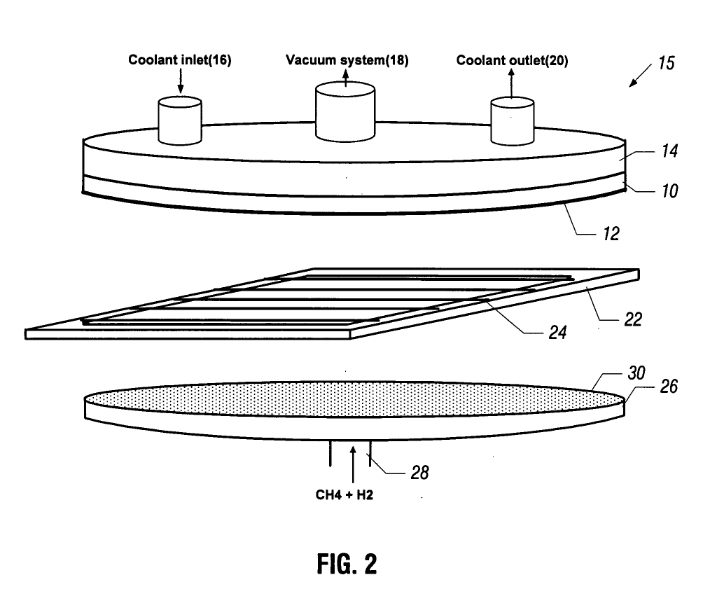

Referring to FIG. 2, a plasma tool 15 may be provided within an enclosed chamber (not shown). The tool 15 may include a vacuum chuck 14 which holds the wafer or substrate 10, covered by the film 12. The chuck 14 may be cooled via coolant introduced into the chuck 14 through a coolant inlet 16 and ejected thru a coolant outlet 20. A vacuum port 18 may provide for suction to releasably hold the substrate 10 on the chuck 14.

Opposed to the film 12 is a shower head 26 having a plurality of apertures 30. A jet of reaction gases is injected into the chamber through the apertures 30 which act as nozzles. In particular, methane and hydrogen gas may be received through an input port 28 and ejected through the apertures 30 into the region of the film 12. The reaction of methane and hydrogen gas, as described previously, results in the deposition of the carbon containing film 12.

The gases that exit through the apertures 30 may be rapidly heated as they pass through a heating frame 22, including heated filaments 24. The filaments 24 may be attached to the peripheral frame 22 to provide rapid heating of the ejected gases. In one embodiment, the filaments 24 may be electrically heated tungsten or rhenium filaments. The filaments 24 may provide relatively high heat in a very short time. In one embodiment, the filaments 24 can be heated to elevated temperatures greater than 200° C. by resistance heating to provide the energy needed to crack the process gases and to generate atomic hydrogen.

As a result of the localized heating of the gas just before it reaches the wafer or substrate 10 and due to the substrate 10 cooling, the heat transferred to the semiconductor wafer or substrate 10 may be reduced. Excessive substrate temperatures may adversely affect components of the substrate 10. To counteract any heating that occurs, the coolant flow continually cools the opposite side of the wafer during the deposition process. In some cases, the substrate 10 may be maintained at a temperature below 450° C., which is sufficient to reduce any adverse impact of temperature.

The wafer temperature control may be modulated by allowing the spacing between the frame 22 and the substrate 10 to be adjusted. The sources of energy to the substrate 12 may include irradiation from the filaments 24, conduction or convection from hot gases near the filaments 24, and heat released by the recombination of atomic hydrogen at the substrate 10 surface. Radiation, conduction, and convection can be reduced by moving the substrate 10 away from the filament array 24.

The growth rate of the diamond film may be enhanced by providing the shower head 26 so that the process gases can be conveyed to the wafer 10, past the filaments 24 at relatively high velocity. This high gas velocity enhances the growth rate of the film 12.

Typically pure diamond films are grown with low concentrations of methane in a super saturation of hydrogen. Since the synthesis of porous diamond films involves mixed phase materials, a higher ratio of methane to hydrogen is used. This higher methane ratio has the added benefit of enhancing film 12 growth rates.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
spraying a mixture of hydrogen and hydrocarbon gas through a heated screen and onto a substrate.

2. The method of claim 1 including spraying hydrocarbon and hydrogen gases through a shower head.

3. The method of claim 1 including spraying said hydrocarbon and hydrogen gases through a screen having heating filaments.

4. The method of claim 3 including heating said filaments to a temperature greater than 200° C.

5. The method of claim 1 including spraying said hydrocarbon and hydrogen gases onto a substrate mounted on a chuck.

6. The method of claim 5 including retaining said substrate on said chuck by vacuum.

7. The method of claim 5 including cooling said chuck.

8. The method of claim 7 including cooling said chuck by liquid coolant flow.

9. The method of claim 1 including providing separate structures to hold said substrate, spray said hydrocarbon and hydrogen gases and heat said hydrocarbon and hydrogen gases and enabling the distances between said structures to be adjusted.

10. The method of claim 1 including forming a plasma from said hydrogen and hydrocarbon gases.

11. The method of claim 10 including forming a diamond containing film on said substrate.

12. A plasma tool comprising:
a nozzle to spray a mixture of hydrogen and hydrocarbon gas towards a substrate; and
a heated screen to convert said gas to a plasma, said screen having openings through which said gas may pass to form a plasma and to reach said substrate.

13. The tool of claim 12 wherein said nozzle is a shower head.

14. The tool of claim 12 wherein said screen includes heated filaments.

15. The tool of claim 12 including a vacuum chuck to hold said substrate.

16. The tool of claim 12 including a cooled chuck to hold said substrate.

17. The tool of claim 16 wherein said chuck includes a passage for liquid coolant flow.

18. The tool of claim 12 wherein the distance between said screen and said substrate may be varied.

19. A method comprising:
forming a diamond film by spraying a mixture of hydrogen and hydrocarbon gas through a heated screen to form a plasma deposited on a substrate; and
cooling said substrate.

20. The method of claim 19 including spraying hydrocarbon and hydrogen gas through a shower head.

21. The method of claim 19 including spraying said hydrocarbon and hydrogen gas through a screen having heating filaments.

22. The method of claim 21 including heating said filaments to a temperature greater than 200° C.

23. The method of claim 19 including spraying said hydrocarbon and hydrogen gas onto a substrate mounted on a chuck.

24. The method of claim 23 including retaining said substrate on said chuck by vacuum.

25. The method of claim 23 including cooling said chuck.

26. The method of claim 25 including cooling said chuck by liquid coolant flow.

27. The method of claim 19 including providing separate structures to hold said substrate, spray said hydrocarbon and hydrogen gas and heat said hydrocarbon and hydrogen gas and enabling the distances between said structures to be adjusted.

28. The method of claim 19 including forming a plasma from said hydrogen and hydrocarbon gases.
